(19) United States
(12) Patent Application Publication
(10) Pub. No.: US 2022/0102230 A1
(43) Pub. Date: Mar. 31, 2022

(54) SEMICONDUCTOR SUBSTRATE AND SEMICONDUCTOR MODULE

(71) Applicant: SONY SEMICONDUCTOR SOLUTIONS CORPORATION, KANAGAWA (JP)

(72) Inventors: HIIZU OHTORII, KANAGAWA (JP); KIWAMU ADACHI, KANAGAWA (JP); NAOKI KAKOIYAMA, KANAGAWA (JP)

(21) Appl. No.: 17/310,568

(22) PCT Filed: Nov. 25, 2019
(86) PCT No.: PCT/JP2019/046006

§ 371 Date: Aug. 11, 2021

(30) Foreign Application Priority Data
Feb. 21, 2019 (JP) 2019-029026

(51) Int. Cl. H01L 23/15; H01L 23/00; H01L 23/13; H05K 1/03

(52) U.S. Cl. CPC H01L 23/15; H01L 23/562; H01L 27/14623; H05K 1/0306; H01L 23/13

(57) ABSTRACT

Provided is a protection structure that appropriately protects a side surface of a glass substrate in a semiconductor module. A semiconductor module is provided with a glass substrate. The glass substrate is provided with a plurality of straight line portions and a corner portion interposed between the straight line portions on a side surface thereof. A protective material is formed on at least a part of the side surface of the glass substrate. The corner portion of the glass substrate is located on an inner side of a straight line connecting ridges of protective materials formed on the straight line portions (a center side of the glass substrate). Therefore, the corner portion is protected against an impact on the side surface of the glass substrate.

### TECHNICAL FIELD

The present technology relates to a semiconductor substrate. In detail, this relates to a protection structure of a semiconductor substrate and a semiconductor module using a glass substrate.

### BACKGROUND ART

In a case where an advanced and large-sized imaging element is mounted using an organic substrate or a ceramic substrate as in a conventional manner, it might be possible that the imaging element floats due to warpage, or connection reliability thereof cannot be maintained due to a difference in thermal expansion coefficient. Therefore, it is required to adopt a glass substrate of which flatness is further ensured. In contrast, since the glass substrate is fragile and is easily damaged by an impact and the like associated with conveyance, it is necessary to protect an outer peripheral portion of the substrate with resin and the like. In this glass substrate, an end face is particularly fragile, and for example, a manufacturing method for forming a protective layer thick on the end face has been proposed (refer to, for example, Patent Document 1).

### CITATION LIST

### Patent Document

Patent Document 1: Japanese Patent Application Laid-Open No. 2015-131741

### SUMMARY OF THE INVENTION

### Problems to be Solved by the Invention

In the above-described conventional technology, an etching resistant layer is provided, and a space surrounded by the etching resistant layer and a side surface of a glass substrate is filled with an end face protecting polymer agent, thereby forming a protective layer in a direction toward the outside of the side surface of the glass substrate. However, in this conventional technology, a process of peeling off after forming the etching resistant layer is required, and warpage might occur on the substrate due to contraction of the protective layer.

The present technology is achieved in view of such a situation, and an object thereof is to provide a protection structure that appropriately protects a side surface of a glass substrate.

### Solutions to Problems

The present technology is achieved for solving the above-described problem, and a first aspect thereof is a semiconductor substrate and a semiconductor module provided with a glass substrate provided with a plurality of straight line portions and a corner portion interposed between the straight line portions described above on a side surface, and a protective material formed on at least a part of the side surface of the glass substrate described above, in which the corner portion described above is located on an inner side of a straight line connecting ridges of protective materials formed on the straight line portions described above. This brings about an effect that the corner portion of the glass substrate is protected by the protective material formed on the straight line portion of the glass substrate.

Furthermore, in the first aspect, the protective material described above may be discontinuous at the corner portion. That is, it is the protective material formed on the straight line portion that brings about the effect of protecting the corner portion.

Furthermore, in the first aspect, the protective material described above may include a material having thixotropy with a thixotropic ratio of 1 to 6. This brings about an effect that the protective material is applied to the side surface of the glass substrate in a state of being highly viscous and bulging outward.

Furthermore, in the first aspect, the protective material described above may include a material having heat resistance to a reflow process. This brings about an effect of coping with a treatment under high temperature for several times in the reflow process after the protective material is applied. Specifically, a material of heat resisting temperature of 200 degrees C. or higher may be used.

Furthermore, in the first aspect, the protective material described above may include a material containing epoxy or silicon as a main component.

Furthermore, in the first aspect, the protective material described above may have a light shielding property against visible light. This brings about an effect of avoiding an influence on an imaging element by external light on the glass substrate in a case where the imaging element is mounted on the glass substrate.

Furthermore, in the first aspect, a wiring layer stacked on at least one of an upper surface or a lower surface of the glass substrate described above may further be provided. In this case, the protective material described above is desirably formed to be lower than a thickness of the wiring layer described above in a thickness direction. This brings about an effect of avoiding an influence of the protective material on the surroundings.

Furthermore, in the first aspect, the protective material described above may include a discontinuous portion at the corner portion described above, and may further include a material different from the protective material described above in the discontinuous portion described above. This brings about an effect of effectively using the corner portion when the glass substrate is fixed in the semiconductor module.

### BRIEF DESCRIPTION OF DRAWINGS

FIG. 1 is a top view illustrating an example of a semiconductor substrate in a first embodiment of the present technology.

FIG. 2 is a top view illustrating a formation example of a protective material 200 in the first embodiment of the present technology.

FIG. 3 is a top view illustrating another formation example of the protective material 200.

FIG. 4 is a cross-sectional view illustrating a formation example of the protective material 200 on a straight line portion 101 of a glass substrate 100 in the first embodiment of the present technology.

FIG. 5 is a cross-sectional view illustrating an example of a semiconductor module in a second embodiment of the present technology.

### MODE FOR CARRYING OUT THE INVENTION

A mode for carrying out the present technology (hereinafter, referred to as an embodiment) is hereinafter described. The description is given in the following order.

1. First Embodiment (Example of Forming Protective Material on Side Surface of Glass Substrate)

2. Second Embodiment (Mounting Example on Semiconductor Module)

### 1. First Embodiment

[Semiconductor Substrate]

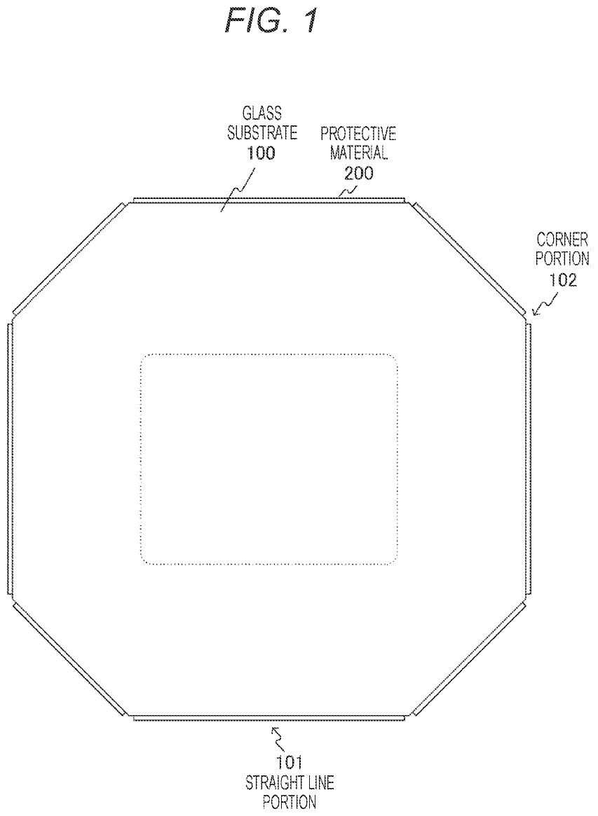

FIG. 1 is a top view illustrating an example of a semiconductor substrate in a first embodiment of the present technology.

The semiconductor substrate is provided with a glass substrate 100 having an octagonal planar shape. That is, the glass substrate 100 is provided with eight straight line portions 101 and corner portions 102 interposed between the straight line portions 101 on a side surface thereof. Note that although the octagonal planar shape is illustrated in this example, this is an example, and the shape may be an arbitrary shape such as a quadrangle or a hexagon.

A protective material 200 is formed on at least a part of the side surface around the glass substrate 100. The protective material 200 includes a material having thixotropy (pseudoplasticity). Thixotropy is a property of viscosity changing with time. Viscosity of a material having thixotropy gradually decreases when a force is applied to the material, and gradually increases when the force is stopped.

The protective material 200 in this embodiment desirably includes a material having thixotropy with a thixotropic ratio of 1 to 6. Having such thixotropy, the protective material 200 is formed on the side surface of the glass substrate 100 in a state of being highly viscous and bulging outward. The protective material 200 is formed by being applied to the glass substrate 100 by a dispenser (liquid fixed volume discharge device).

Furthermore, on the glass substrate 100, in order to perform solder joint, solder reflow is performed as a post-process after forming the protective material 200. In this solder reflow process, treatment under high temperature is performed several times. For example, temperature of 260 degrees C is maintained for 30 seconds. Therefore, it is necessary to avoid contraction of the protective material 200 in the solder reflow process and deformation of the glass substrate 100 by a stress accompanying the contraction.

Therefore, the material of the protective material 200 desirably has heat resistance to the solder reflow process. More specifically, the material of the protective material 200 is desirably the material of heat resisting temperature (thermal deformation temperature) of 200 degrees C. or higher. As such material, for example, a resin containing epoxy or silicone as a main component is assumed.

Note that the glass substrate 100 may have a structure in which glass, an insulating material, and a conductive material are stacked, for example, in addition to a structure using glass as a material. In this case, these stacked materials are exposed to an end face of the substrate, but even in this case, protection by the protective material 200 is applicable.

[Formation of Protective Material]

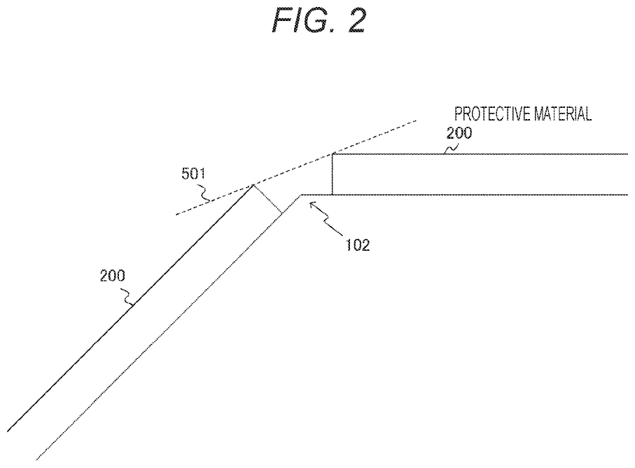

FIG. 2 is a top view illustrating a formation example of the protective material 200 in the first embodiment of the present technology.

Even if the protective material 200 is applied to the corner portion 102, this tends to be thin due to surface tension, and a film thickness and a shape thereof tend to be unstable. Furthermore, an end face might have a convex shape due to an influence of wet etching used at the time of substrate separation, and the protective material 200 might be thinner. Then, in this example, the protective material 200 is formed on the straight line portion 101 on the side surface of the glass substrate 100, and is not formed on the corner portion 102. That is, the protective material 200 is discontinuous at the corner portion 102. Then, the protective material 200 is not daringly formed on the corner portion 102 and the corner portion 102 is protected by the protective material 200 formed on the straight line portion 101. However, as described later, there is a case where the protective material 200 may be formed on the corner portion 102.

Here, a straight line 501 connecting ridges of the protective materials 200 formed on the straight line portions 101 of the glass substrate 100 is assumed. The ridge is a straight line in contact with mountains of the protective materials 200 formed on the adjacent straight line portions 101. At that time, the corner portion 102 of the glass substrate 100 is located on an inner side of the straight line 501 (a center side of the glass substrate 100). Therefore, even when an impact is applied to the glass substrate 100 from an object on the straight line, the corner portion 102 is protected against the impact.

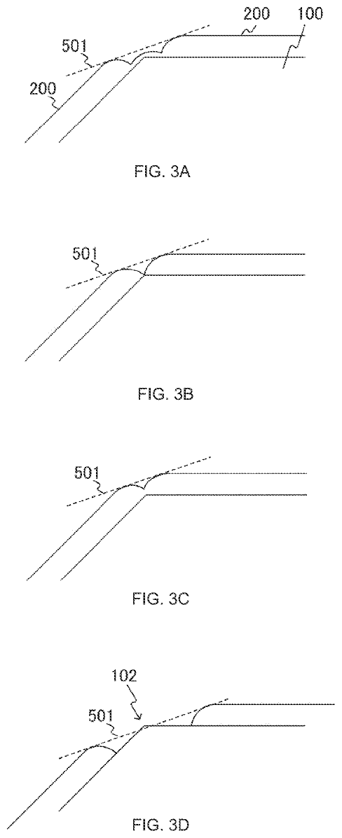

FIG. 3 is a top view illustrating another formation example of the protective material 200.

In the above-described example, the protective material 200 is discontinuous at the corner portion 102, but in a of FIG. 3, the protective material 200 is also formed on the corner portion 102. In this case also, the protective material 200 on the corner portion 102 of the glass substrate 100 is located on an inner side of the straight line 501. Therefore, in this case also, even when an impact is applied to the glass substrate 100 from an object on the straight line, the impact does not reach even the protective material 200 on the corner portion 102, and this is protected against the impact.

In b of FIG. 3, the protective materials 200 formed on the straight line portions 101 of the glass substrate 100 are in contact with each other. Furthermore, in c of FIG. 3, the protective materials 200 formed on the straight line portions 101 of the glass substrate 100 become closer and integrated with each other. In these cases also, even when an impact is applied to the glass substrate 100 from an object on the straight line, the corner portion 102 is protected against the impact.

In contrast, in a case of d of FIG. 3, the corner portion 102 of the glass substrate 100 is located on an outer side of the straight line 501 (an opposite side of the center of the glass substrate 100). In this case, when an impact is applied from an object on the straight line to the corner portion 102 of the glass substrate 100, the protective material 200 formed on the straight line portion 101 cannot protect the corner portion 102 and the impact reaches the same.

Therefore, it may be seen that an effect as this embodiment of protecting the corner portion 102 is exhibited in the formation examples in a to c of FIG. 3. For example, even if a position of the protective material 200 of the straight line portion 101 is displaced or the protective material 200 is applied to the corner portion 102 due to variation and the like at the time of manufacturing, this serves as the protective material 200 of this embodiment in the formation examples in a to c of FIG. 3.

[Dimension of Protective Material]

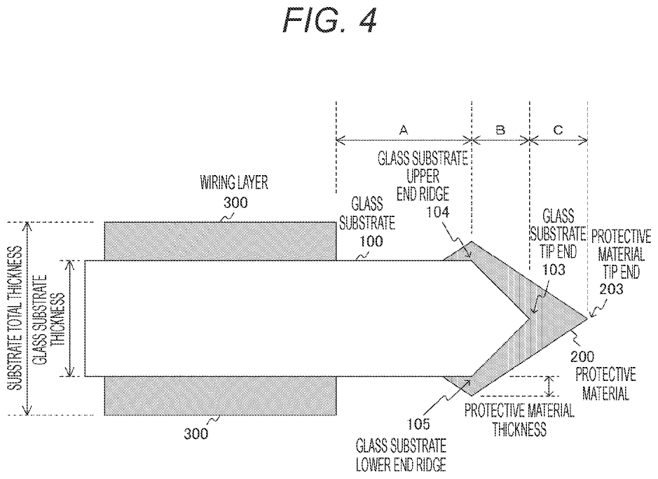

FIG. 4 is a cross-sectional view illustrating a formation example of the protective material 200 on the straight line portion 101 of the glass substrate 100 in the first embodiment of the present technology.

When the glass substrate 100 is used as the semiconductor substrate, a wiring layer 300 is provided on at least one of an upper surface or a lower surface of the glass substrate 100 to be used as a wiring substrate. The wiring layer 300 is formed by stacking a polyimide-based insulating material and a metal conductive material. Therefore, a substrate total thickness when used as the wiring substrate is obtained by adding a thickness of the wiring layer 300 to a thickness of the glass substrate 100. For example, the thickness of the glass substrate 100 is assumed to be about 800 μm. Furthermore, the thickness of the wiring layer 300 is assumed to be about 20 to 40 μm.

As described above, since the material having thixotropy is assumed as the protective material 200, a cross-sectional shape of the protective material 200 is a shape bulging outward along the side surface of the glass substrate 100. At that time, when focusing on a height direction (thickness direction), an upper end ridge 104 and a lower end ridge 105 of the glass substrate 100 are widest portions. Therefore, when the protective material 200 on the upper end ridge 104 and the lower end ridge 105 is formed to be lower than a height of the wiring layer 300, there is not a practical problem as the wiring substrate.

In contrast, when focusing on a length direction (side surface direction), a thickness (C in FIG. 4) of a tip end 203 of the protective material 200 at a tip end 103 of the glass substrate 100 is desirably thicker than that of other portions. This is for preventing damage on the end face. As described above, since the material having thixotropy is assumed as the protective material 200, this is suitable for obtaining such shape.

As an example of a dimension, a distance (A in FIG. 4) from an end of the wiring layer 300 to the upper end ridge 104 or the lower end ridge 105 of the glass substrate 100 is assumed to be, for example, about 450 to 500 μm. Furthermore, a distance (B in FIG. 4) from the upper end ridge 104 or the lower end ridge 105 of the glass substrate 100 to the tip end 103 of the glass substrate 100 is assumed to be, for example, about 200 to 250 μm. Furthermore, the thickness (C in FIG. 4) of the tip end 203 of the protective material 200 at the tip end 103 of the glass substrate 100 is assumed to be, for example, about 200 μm.

Note that, although a shape in which the end face of the glass substrate 100 protrudes outward is illustrated in this example, the shape may be such that the center in the thickness direction recedes toward the substrate from both the ends in the thickness direction, for example.

In this manner, in the first embodiment of the present technology, the corner portion 102 of the glass substrate 100 or the protective material 200 on the corner portion 102 is formed on an inner side of the straight line 501 connecting the ridges of the protective materials 200 formed on the straight line portions 101 of the glass substrate 100. Therefore, even when an impact is applied to the glass substrate 100 from an object on the straight line, the corner portion 102 may be protected against the impact.

### 2. Second Embodiment

[Semiconductor Module]

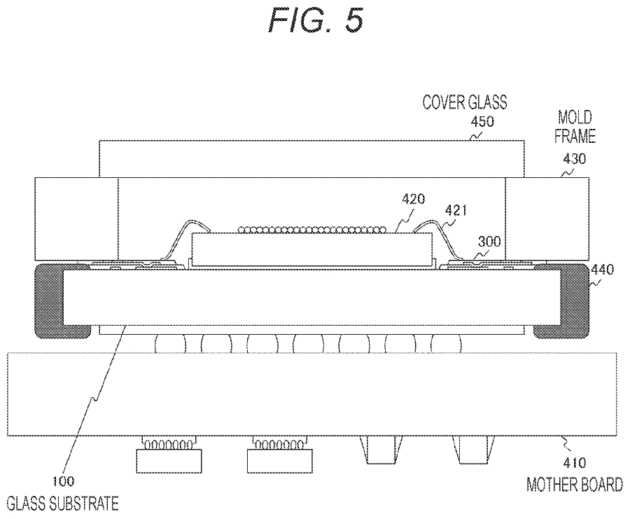

FIG. 5 is a cross-sectional view illustrating an example of a semiconductor module in a second embodiment of the present technology.

This semiconductor module includes the semiconductor substrate in the first embodiment described above. That is, a semiconductor chip 420 is mounted on an upper surface of a glass substrate 100. In this example, the semiconductor module for an imaging device on which an imaging element (image sensor) is mounted is assumed as the semiconductor chip 420. Each electrode of the semiconductor chip 420 is connected to a wiring layer 300 by means of a bonding wire 421.

A cover glass 450 is arranged on an upper side, that is, on an incident light side of the glass substrate 100. In order to fix the cover glass 450, a mold frame 430 is formed around the glass substrate 100. The mold frame 430 is fixed by a fixing material 440 at a corner portion 102 of the glass substrate 100. That is, a portion in which the above-described protective material 200 is discontinuous is filled with a material different from the protective material 200 at a post-process. Note that the fixing material 440 is an example of a “material different from a protective material” recited in claims.

The glass substrate 100 on a lower side of which a solder bump and the like is provided is mounted on a mother board 410. Another semiconductor chip may be further mounted on the mother board 410. In this manner, the semiconductor module is formed.

Since it is assumed that the imaging element is mounted as the semiconductor chip 420 in this semiconductor module, the protective material 200 of the glass substrate 100 desirably has a light shielding property against visible light. Therefore, it is possible to avoid an influence of external light on the semiconductor chip 420 on the glass substrate 100.

In this manner, in the second embodiment of the present technology, the corner portion 102 of the glass substrate 100 on which the semiconductor chip 420 is mounted or the protective material 200 thereof is formed on an inner side of a straight line 501 connecting ridges of the protective materials 200 formed on straight line portions 101 of the glass substrate 100. Therefore, even when an impact is applied to the glass substrate 100 of the semiconductor module from an object on the straight line, the corner portion 102 of the glass substrate 100 may be protected against the impact.

Note that the above-described embodiments describe an example of embodying the present technology, and there is a correspondence relationship between items in the embodiments and the matters specifying the invention in claims. Similarly, there is a correspondence relationship between the matters specifying the invention in claims and the matters in the embodiments of the present technology having the same names. However, the present technology is not limited to the embodiments and may be embodied by variously modifying the embodiments without departing from the gist thereof.

Note that the effect described in this specification is illustrative only and is not limitative; there may also be another effect.

Note that the present technology may also have a following configuration.

(1) A semiconductor substrate provided with:

a glass substrate provided with a plurality of straight line portions and a corner portion interposed between the straight line portions on a side surface; and

a protective material formed on at least a part of the side surface of the glass substrate, in which

the corner portion is located on an inner side of a straight line connecting ridges of protective materials formed on the straight line portions.

(2) The semiconductor substrate according to (1) described above, in which

the protective material is discontinuous at the corner portion.

(3) The semiconductor substrate according to (1) or (2) described above, in which

the protective material includes a material having thixotropy with a thixotropic ratio of 1 to 6.

(4) The semiconductor substrate according to any one of (1) to (3), in which

the protective material includes a material having heat resistance to a reflow process.

(5) The semiconductor substrate according to any one of (1) to (4), in which

the protective material includes a material of heat resisting temperature of 200 degrees C. or higher.

(6) The semiconductor substrate according to any one of (1) to (5) described above, in which

the protective material includes a material containing epoxy or silicone as a main component.

(7) The semiconductor substrate according to any one of (1) to (6) described above, in which

the protective material has a light shielding property against visible light.

(8) The semiconductor substrate according to any one of (1) to (7), further provided with:

a wiring layer stacked on at least one of an upper surface or a lower surface of the glass substrate.

(9) The semiconductor substrate according to (8) described above, in which

the protective material is formed to be lower than a thickness of the wiring layer in a thickness direction.

(10) A semiconductor module provided with:

a glass substrate provided with a plurality of straight line portions and a corner portion interposed between the straight line portions on a side surface; and

a protective material formed on at least a part of the side surface of the glass substrate, in which

the corner portion is located on an inner side of the glass substrate as compared to a straight line connecting ridges of protective materials formed on the straight line portions.

(11) The semiconductor module according to (10) described above, in which

the protective material includes a discontinuous portion at the corner portion, and

further includes a material different from the protective material in the discontinuous portion.

### REFERENCE SIGNS LIST

100 Glass substrate
101 Straight line portion of glass substrate
102 Corner portion of glass substrate
103 Tip end of glass substrate
104 Upper end ridge of glass substrate
105 Lower end ridge of glass substrate
200 Protective material
203 Tip end of protective material
300 Wiring layer
410 Mother board
420 Semiconductor chip
421 Bonding wire
430 Mold frame
440 Fixing material
450 Cover glass
501 Straight line connecting ridges of protective materials

1. A semiconductor substrate comprising:
a glass substrate provided with a plurality of straight line portions and a corner portion interposed between the straight line portions on a side surface; and
a protective material formed on at least a part of the side surface of the glass substrate, wherein
the corner portion is located on an inner side of a straight line connecting ridges of protective materials formed on the straight line portions.

2. The semiconductor substrate according to claim 1, wherein
the protective material is discontinuous at the corner portion.

3. The semiconductor substrate according to claim 1, wherein
the protective material includes a material having thixotropy with a thixotropic ratio of 1 to 6.

4. The semiconductor substrate according to claim 1, wherein
the protective material includes a material having heat resistance to a reflow process.

5. The semiconductor substrate according to claim 1, wherein
the protective material includes a material of heat resisting temperature of 200 degrees C. or higher.

6. The semiconductor substrate according to claim 1, wherein
the protective material includes a material containing epoxy or silicone as a main component.

7. The semiconductor substrate according to claim 1, wherein
the protective material has a light shielding property against visible light.

8. The semiconductor substrate according to claim 1, further comprising:
a wiring layer stacked on at least one of an upper surface or a lower surface of the glass substrate.

9. The semiconductor substrate according to claim 8, wherein
the protective material is formed to be lower than a thickness of the wiring layer in a thickness direction.

10. A semiconductor module comprising:
a glass substrate provided with a plurality of straight line portions and a corner portion interposed between the straight line portions on a side surface; and
a protective material formed on at least a part of the side surface of the glass substrate, wherein
the corner portion is located on an inner side of the glass substrate as compared to a straight line connecting ridges of protective materials formed on the straight line portions.

11. The semiconductor module according to claim 10, wherein
the protective material includes a discontinuous portion at the corner portion, and
further includes a material different from the protective material in the discontinuous portion.
